(19) United States
(12) Patent Application Publication
(10) Pub. No.: US 2018/0108943 A1
(43) Pub. Date: Apr. 19, 2018

(54) SOLID ELECTROLYTE COMPOSITION, METHOD FOR PREPARING SAME, AND METHOD FOR MANUFACTURING ALL-SOLID-STATE BATTERY USING SAME

(71) Applicant: Electronics and Telecommunications Research Institute, Daejeon (KR)

(72) Inventors: Dong Ok SHIN, Daejeon (KR); Young-Gi LEE, Daejeon (KR); Kwang Man KIM, Daejeon (KR); Ju Young KIM, Daejeon (KR)

(73) Assignee: Electronics and Telecommunications Research Institute, Daejeon (KR)

(21) Appl. No.: 15/646,080

(22) Filed: Jul. 10, 2017

(30) Foreign Application Priority Data
Oct. 19, 2016 (KR) 10-2016-0136050
Mar. 9, 2017 (KR) 10-2017-0030288

(51) Int. Cl. H01M 10/0562; C23C 2/04; C23C 16/455; H01M 10/0585; H01M 4/04; H01M 10/04; C09D 123/08; C09D 5/24; C09D 127/16

(52) U.S. Cl. CPC H01M 10/0562; C23C 2/04; C23C 16/45525; H01M 10/0585; C09D 127/16; H01M 10/04; C09D 123/0853; C09D 5/24; H01M 4/04

(57) ABSTRACT

Provided is a solid electrolyte composition including a solid electrolyte with a protective layer provided on a surface thereof, and a polymer binder. The protective layer includes at least one of an inorganic layer, including at least one of an oxide, a nitride, and a sulfide, an organic layer, including a polydopamine derivative, and a self-assembled monolayer, including an organosilane.

### CROSS-REFERENCE TO RELATED APPLICATIONS

This U.S. non-provisional patent application claims priority under 35 U.S.C. § 119 of Korean Patent Application Nos. 10-2016-0136050, filed on Oct. 19, 2016, and 10-2017-0030288, filed on Mar. 9, 2017, the entire contents of which are hereby incorporated by reference.

### BACKGROUND

The present invention relates to a solid electrolyte composition including a chalcogenide solid electrolyte, a method for preparing the same, and a method for preparing an all-solid-state battery using the same.

As the demand for mobile power sources increases, interest is increasing in lithium secondary batteries, which exhibit higher output and stability, and have superior charge-discharge properties and higher energy densities compared to existing secondary batteries, as energy sources for mobile electronic devices.

A lithium secondary battery is composed of a positive electrode, a negative electrode, an electrolyte, and a separator. As lithium ions move between the positive electrode and the negative electrode through the separator according to oxidation and reduction reactions with the electrodes, electrons flow through external wiring to charge or discharge electricity. Since the movement of the lithium ions inside the battery occurs through the electrolyte, the ionic conductivity of lithium in the electrolyte affects the lifetime, capacity, reversibility, and charge-discharge rate of the battery. The electrolyte in the lithium secondary battery is divided into liquid organic electrolytes, which include lithium salts, polymer electrolytes (polymer type or gel type), and inorganic solid electrolytes. Although the liquid organic electrolytes are widely used due to having high ionic conductivity and stable electrochemical properties, many limitations regarding the stability thereof are being brought up, such limitations being the result of volatility and leakage. The inorganic solid electrolytes are receiving attention due to increased capacity, process simplification, and stability.

### SUMMARY

The present disclosure provides a solid electrolyte composition, in which the formation of a stable protective layer enables wet processing, and a method for preparing the same.

The present disclosure also provides a method for manufacturing an all-solid-state battery, which is easy to manufacture, and in which surface area expansion is convenient.

Objects of the present disclosure are not limited to those mentioned above, and other unmentioned objects may be clearly understood by a person skilled in the art from the text below.

An embodiment of the inventive concept provides a solid electrolyte composition including a solid electrolyte with a protective layer provided on a surface thereof; and a polymer binder, wherein the protective layer includes at least one of an inorganic layer, including at least one of an oxide, a nitride, and a sulfide, an organic layer, including a polydopamine derivative, and a self-assembled monolayer, including an organosilane.

In an embodiment of the inventive concept, a method for preparing a solid electrolyte composition includes providing a solid electrolyte; forming a protective layer on a surface of the solid electrolyte; providing a base solution, in which a polymer binder is dissolved in an aprotic solvent; and adding to the base solution, the solid electrolyte provided with the protective layer, wherein the protective layer includes at least one of an inorganic layer, including at least one of an oxide, a nitride, and a sulfide, an organic layer, including a polydopamine derivative, and a self-assembled monolayer, including an organosilane.

In an embodiment of the inventive concept, a method for manufacturing an all-solid-state battery includes providing a positive electrode layer and a negative electrode layer; and forming a solid electrolyte layer by performing wet processing using a solid electrolyte composition, wherein, the solid electrolyte layer is provided between the positive electrode layer and the negative electrode layer, and the solid electrolyte composition includes a solid electrolyte with a protective layer provided on a surface thereof, an aprotic solvent, and a polymer binder, the protective layer including at least one of an inorganic layer, including at least one of an oxide, a nitride, and a sulfide, an organic layer, including a polydopamine derivative, and a self-assembled monolayer, including an organosilane.

### BRIEF DESCRIPTION OF THE FIGURES

FIG. 1 is a flow chart illustrating a method for preparing a solid electrolyte composition according to embodiments of the inventive concept;

FIG. 2 is a conceptual diagram illustrating a method for forming a protective layer on a surface of a solid electrolyte;

FIG. 3 is a flow chart illustrating a method for manufacturing an all-solid-state battery using a solid electrolyte composition according to embodiments of the inventive concept;

FIG. 4 is a cross-sectional view of an all-solid-state battery manufactured according to embodiments of the inventive concept;

FIG. 5 is an electron microscopy image of a solid electrolyte with a protective layer provided on the surface thereof;

FIG. 6 is a graph analyzing the ionic conductivity of a chalcogenide solid electrolyte when a self-assembled monolayer is provided on the surface thereof;

FIG. 7 is a graph analyzing the ionic conductivity of a solid electrolyte film prepared by coating with a solid electrolyte composition; and

FIG. 8 is a graph illustrating the performance of a half-cell manufactured by coating a solid electrolyte composition directly onto an electrode.

### DETAILED DESCRIPTION

In order to provide sufficient understanding of the features and effects of the present invention, exemplary embodiments of the present invention are described with reference to the accompanying drawings. However, the present invention is not limited to the embodiments disclosed below, and may be embodied in various forms and modified in various ways. These embodiments are provided so that this disclosure will be thorough and complete, and will fully convey the scope of the inventive concept to those skilled in the art. In the drawings, the dimensions of elements are exaggerated for clarity of illustration, and the ratios of each of the elements may be exaggerated or reduced.

Unless otherwise defined, all terms used herein have the same meaning as commonly understood by one of ordinary skill in the art to which this invention belongs. Hereinafter, the present invention will be described in detail by describing exemplary embodiments thereof with reference to the accompanying drawings.

According to embodiments of the inventive concept, a solid electrolyte composition may include a solid electrolyte with a protective layer provided on a surface thereof, an aprotic solvent, and a polymer binder. The solid electrolyte may be a chalcogenide solid electrolyte. According to some embodiments, the solid electrolyte may be a chalcogenide solid electrolyte that includes a sulfide. The solid electrolyte may include lithium. For example, the solid electrolyte may include at least one of Li₁₀SnP₂S₁₂, Li₄₋ₓSn₁₋ₓAsₓS₄ (x=0-100), Li_{3.25}Ge_{0.25}P_{0.75}S₄, Li₁₀GeP₂S₁₂Li₆PS₅Cl, Li₂SP₂S₅, (x)Li₂S(100-x)P₂S₅ (x=0-100), Li₂P₂S₅, Li₂SSiS₂Li₃N, Li₂SP₂S₅LiI, (100−x)(0.6Li₂S·0.4SiS₂)·xLixMOy (M=Si, P, Ge, B, Al, Ga, or In, x=0-100, y is a value determined by x in order to achieve electroneutrality), Li₂SGeS₂, and Li₂SB₂S₃LiI.

The protective layer may include at least one of an inorganic layer, including at least one of an oxide, a nitride, and a sulfide; an organic layer, including a polydopamine derivative; and a self-assembled monolayer, including an organosilane. The oxide, for example, may include at least one of C, Al, Si Ti, Fe, Co, Ni, Cu, Zn, Ga, Ge, Mo, Ru, Rh, Pd, Ag, Ta, W, Pt, Li, Be, B, Mg, Al, Si, P, Ca, Sc, Ti, V, Cr, Mn, Fe, Co, Ni, Cu, Zn, Ga, Ge, Sr, Y, Zr, Nb, Ru, Rh, Pd, In, Sn, Sb, Ba, La, Ce, Pr, Nd, Sm, Eu, Gd, Tb, Yb, Lu, Hf, W, Ir, Pt, and Pb. The nitride, for example, may include at least one of B, Al, Si, Ti, Cu, Ga, Zr, Nb, Mo, In, Hf, Ta, and W. The sulfide, for example, may include at least one of Ca, Ti, Mn, Cu, Zn, Sr, Y, Cd, In, Sn, Sb, Ba, La, and W. The polydopamine derivative may include a chemical substance mimicking a thread-like mussel foot protein (Mytilus edulis foot protein 5; Mefp-5) which enables mussels to stay attached to surfaces of rocks while subjected to strong ocean currents.

The self-assembled monolayer may be a monolayer that is formed as a head group of an organic material achieves close-packing by being chemically adsorbed onto a surface of a solid. Specifically, the organosilane having a head group of a hydroxy group (—OH) may be provided on the surface of the solid electrolyte. For example, when the organosilane is alkyl-trichlorosilane, a Si—Cl bond in the organosilane may be hydrolyzed to form a Si—OH bond, and accordingly, the organosilane may have the head group of the hydroxy group (—OH). A natural oxide layer may be formed on the surface of the solid electrolyte, and a hydroxy group (—OH) may be formed on the surface of the solid electrolyte. Through a condensation reaction between the hydroxy group (—OH) of the solid electrolyte and the hydroxy group (—OH) of the organosilane, Si—O—Si bonds may be formed between adjacent head groups of the organosilane. The adjacent head groups of the organosilane may be adsorbed onto the surface of the solid electrolyte as the adjacent head groups achieve close-packing through the Si—O—Si bonds, and accordingly, an organosilane monolayer may be formed on the surface of the solid electrolyte. The organosilane, for example, may be an organic material selected from the group consisting of phenethyltrichlorosilane (PETCS), phenyltrichlorosilane (PTCS), benzyltrichlorosilane (BZTCS), tolyltrichlorosilane (TTCS), 2-{(trimethoxysilyl)ethyl}-2-pyridine (PYRTMS), 4-biphenylyltrimethowysilane (BPTMS), octadecyltrichlorosilane (OTS), 1-naphthyltrimehtoxysilane (NAPTMS), 1-{(trimethoxysilyl)methyl}naphthalene (MNATMS), (9-methylanthracenyl)trimethoxysilane (MANTMS}, 3-aminopropyltriethoxysilane (APTES), and derivatives thereof.

The protective layer may have a thickness that enables movement of ions (for example, Li⁺) through the solid electrolyte. For example, the thickness of the protective layer may range from about 0.1 to 500 nm. When the thickness of the protective layer exceeds 500 nm, movement of the ions through the solid electrolyte may be difficult.

The aprotic solvent may include a material which does not react with the solid electrolyte, but is capable of dissolving the polymer binder. The aprotic solvent, for example, may include at least one of tetrahydrofuran (THF), acetone, dimethylformamide (DMF), dimethylsulfoxide (DMSO), n-methylpyrrolidone (NMP), benzene, chlorobenzene, n-hexane, toluene, xylene, n-octane, acetonitrile (AN), diethylether, dichloromethane, ethylacetate, cyclohexane, pentane, chloroform, and methylethylketone (MEK).

The polymer binder may include a polymer material that dissolves in the aprotic solvent. For example, the polymer binder may include at least one of polyethylene, polypropylene, ethylene-vinylacetate copolymer, ethylene-vinylalcohol copolymer, ethylene-vinylacetylic acid copolymer, butadiene rubber, styrene butadiene rubber, and nitrile butadiene rubber. The polymer binder may be provided in a weight range that does not obstruct ion conduction pathways of the solid electrolyte. The weight ratio of the solid electrolyte provided with the protective layer, and the polymer binder may range from about 99.9:0.1 to about 50:50.

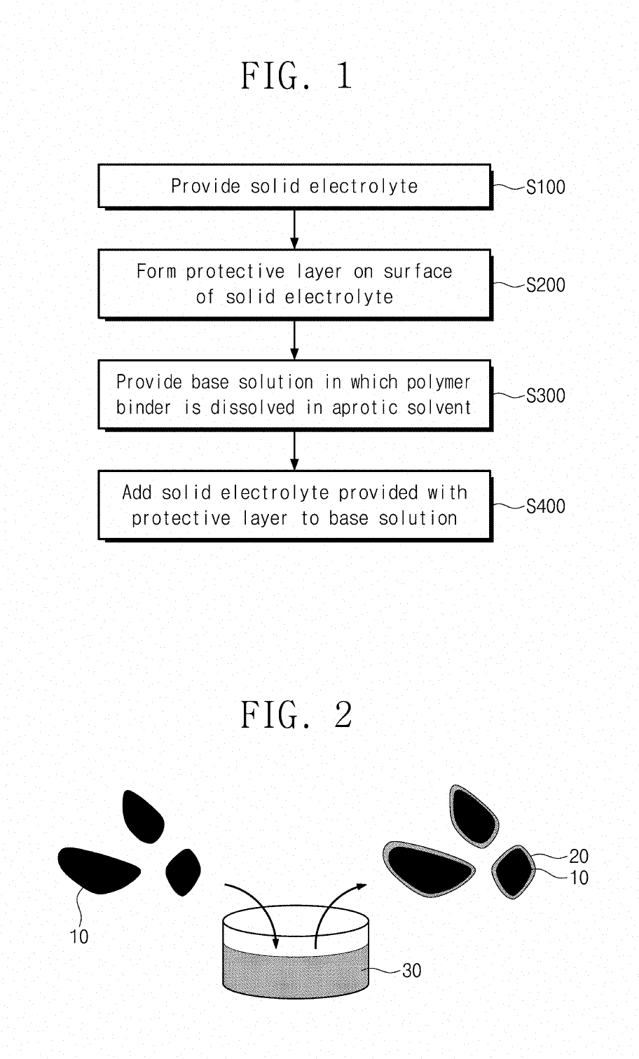

FIG. 1 is a flow chart illustrating a method for preparing a solid electrolyte composition according to embodiments of the inventive concept. FIG. 2 is a conceptual diagram illustrating a method for forming a protective layer on a surface of a solid electrolyte. For conciseness of description, descriptions repeating those given above for a solid electrolyte composition according to embodiments of the inventive concept may be excluded.

Referring to FIGS. 1 and 2, a solid electrolyte 10 may be provided (S100). The solid electrolyte 10 may be a chalcogenide solid electrolyte. According to some embodiments, the solid electrolyte 10 may be a chalcogenide solid electrolyte that includes a sulfide. The solid electrolyte 10 may include lithium.

A protective layer 20 may be provided on a surface of the solid electrolyte 10 (S200). The protective layer may include at least one of an inorganic layer, including at least one of an oxide, a nitride, and a sulfide; an organic layer, including a polydopamine derivative; and a self-assembled monolayer, including an organosilane.

As illustrated in FIG. 2, the organic layer and the self-assembled monolayer may be formed using a dip-coating method. Specifically, the organic layer may be formed on the surface of the solid electrolyte 10 after a predetermined reaction time has passed after dipping of the solid electrolyte 10 into a solution 30 having the polydopamine derivative dissolved therein. The concentration of the polydopamine derivative in the solution 30 may range from about 1 mM to about 1 M. The solution 30 may be formed using a solvent selected from among toluene, hexane, chloroform, diethylether, cyclohexane, benzene, and combinations thereof. The self-assembled monolayer may be formed on the surface of the solid electrolyte 10 after a predetermined reaction time has passed after dipping of the solid electrolyte 10 into the solution 30 having the organosilane dissolved therein. The concentration of the organosilane in the solution 30 may range from about 1 mM to about 1 M. The solution 30 may be formed using a solvent selected from among toluene, hexane, chloroform, diethylether, cyclohexane, benzene, and combinations thereof. The reaction time for the dip-coating process may range from about 0.1 to 24 hours. Unlike the illustration in FIG. 2, the inorganic layer may be formed using an atomic layer deposition method. Specifically, formation of the inorganic layer may include forming a thin film, including at least one of the oxide, the nitride, and the sulfide, on the surface of the solid electrolyte 10 by performing an atomic layer deposition process. The protective layer 20 may be formed to have a thickness of about 0.1 to 500 nm.

Referring to FIG. 1, a base solution including a polymer binder dissolved in an aprotic solvent may be provided (S300). The aprotic solvent may include a material that does not react with the solid electrolyte, and the polymer binder may include a polymer material that dissolves in the aprotic solvent. The concentration of the polymer binder in the base solution may range from about 1 to 50 wt %.

The solid electrolyte 10 provided with the protective layer 20 may be mixed into the base solution (S400). The solid electrolyte 10 provided with the protective layer 20 may be provided to the base solution so as to have a weight ratio of about 99.9:0.1 to about 50:50 with respect to polymer binder. That is, in the base solution, the weight ratio of the solid electrolyte 10 provided with the protective layer 20 to the polymer binder may range from about 99.9:0.1 to about 50:50. Through the mixing, a solid electrolyte composition including the solid electrolyte 10, on which the protective layer 20 is provided, the aprotic solvent, and the polymer binder may be formed.

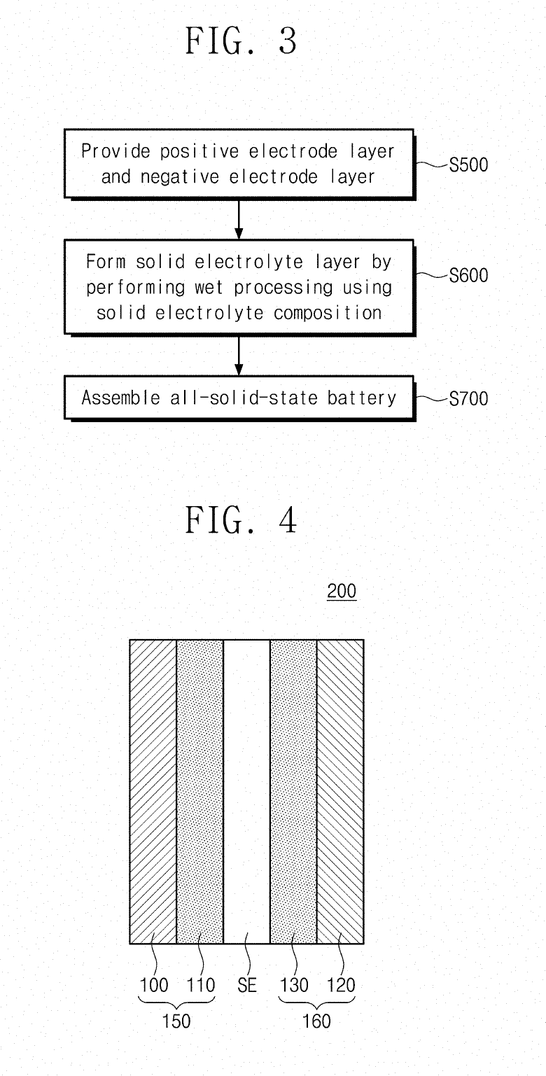

FIG. 3 is a flow chart illustrating a method for manufacturing an all-solid-state battery using a solid electrolyte composition according to embodiments of the inventive concept, and FIG. 4 is a cross-sectional view of an all-solid-state battery manufactured according to embodiments of the inventive concept.

Referring to FIGS. 3 and 4, each of a positive electrode layer 150 and a negative electrode layer 160 may be provided. The positive electrode layer 150 may include a positive electrode active layer 110 capable of receiving ions (for example, Li+) from a solid electrolyte layer SE to be described below, and a first current collector 100 which is laminated on a face of the positive electrode active layer 110 and transfers electrons to the positive electrode active layer 110. The negative electrode layer 160 may include a negative electrode active layer 130 capable of receiving ions (for example, Li+) from the solid electrolyte layer SE, and a second current collector 120 which is laminated on a face of the negative electrode active layer 130 and transfers electrons to the negative electrode active layer 130. The positive electrode layer 150 and the negative electrode layer 160 may include conductive materials.

The solid electrolyte layer SE may be formed by performing a wet processing using a solid electrolyte composition (S600). The solid electrolyte composition may be the solid electrolyte composition according to embodiments of the inventive concept. As described above, the solid electrolyte composition may include the solid electrolyte, on which the protective layer is provided, the aprotic solvent, and the polymer binder. The solid electrolyte may be a chalcogenide solid electrolyte. According to some embodiments, the solid electrolyte may be a chalcogenide solid electrolyte that includes a sulfide. The solid electrolyte may include lithium. The wet processing may be performed using, for example, a method such as dip-coating, spray coating, or screen printing and the like. According to some embodiments, formation of the solid electrolyte layer SE may include forming a thin film on a separate supporting substrate by performing the wet processing using the solid electrolyte composition, forming a solid electrolyte film by drying the thin film, and transferring the solid electrolyte film onto the positive electrode layer 150 or the negative electrode layer 160. According to other embodiments, formation of the solid electrolyte layer SE may include forming a thin film on the positive electrode layer 150 or the negative electrode layer 160 by performing the wet processing using the solid electrolyte composition, and forming the solid electrolyte layer SE by drying the thin film. In this case, the solid electrolyte layer SE may be formed directly on the positive electrode layer 150 or the negative electrode layer 160.

The solid electrolyte layer SE may include the solid electrolyte with the protective layer provided on the surface thereof, and the polymer binder. The aprotic solvent may be removed during the course of drying the thin film. The thickness of the protective layer may range from about 0.1 to 500 nm. The weight ratio of the solid electrolyte provided with the protective layer, and the polymer binder may range from about 99.9:0.01 to about 50:50. Accordingly, ionic conduction may be possible in the solid electrolyte layer SE.

An all-solid-state battery 200 may be assembled using the positive electrode layer 150, the negative electrode layer 160, and the solid electrolyte layer SE (S700). The solid electrolyte layer SE may be interposed between the positive electrode layer 150 and the negative electrode layer 160. In the positive electrode layer 150, the first current collector 100 may be disposed to be spaced apart from the solid electrolyte layer SE with the positive electrode active layer 110 interposed therebetween. In the negative electrode 160, the second current collector 120 may be disposed to be spaced apart from the solid electrolyte layer SE with the negative electrode active layer 130 interposed therebetween. Although not shown, the assembled all-solid-state battery 200 may be enclosed in a battery case.

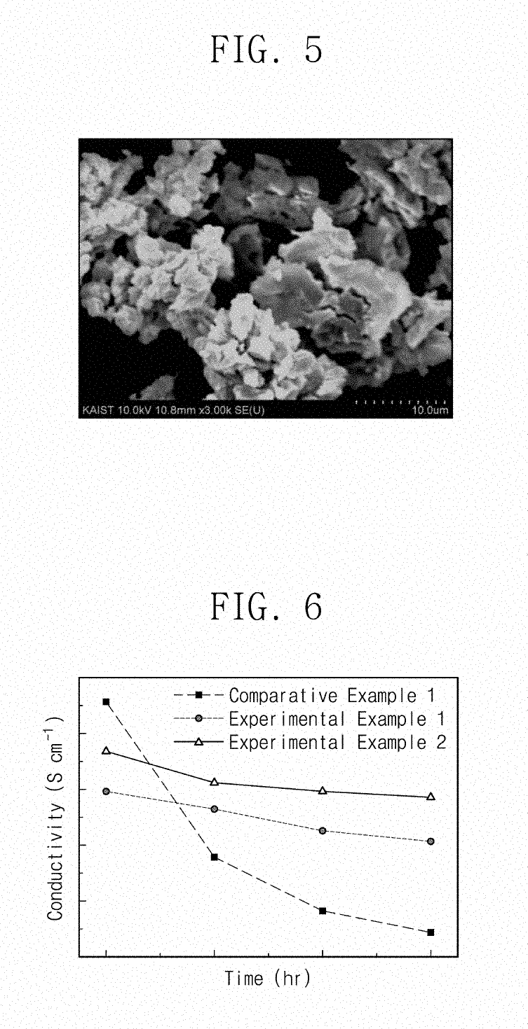

FIG. 5 is an electron microscopy image of a solid electrolyte with a protective layer provided on a surface thereof. FIG. 6 is a graph analyzing the ionic conductivity of a chalcogenide solid electrolyte when a self-assembled monolayer is provided on a surface thereof.

### Experimental Example 1

A sulfide solid electrolyte having a glass-ceramic structured 75Li₂S25P₂S₅ (Li₇P₃S₁₁) composition was selected as a chalcogenide solid electrolyte. A mixed solution was prepared by adding 3-aminopropyltriethoxysilane (APTES) in a concentration of 1 mM to a toluene solution, and stirring at room temperature. About 1 g of a powder of the solid electrolyte was placed into the mixed solution and reacted for about 1 to 5 hours. Upon completion of the reaction, the powder of the solid electrolyte was taken out and washed with toluene to wash away physically adhered organic material. Afterwards, the powder of the solid electrolyte was dried at about 50 to 70° C. to form an APTES self-assembled monolayer on a surface of the solid electrolyte. The process described above was performed inside a glove box removed of moisture and oxygen. A protective layer (the APTES self-assembled monolayer) was provided on the surface of the chalcogenide solid electrolyte according to the process described above. An image of the solid electrolyte provided with the protective layer could be observed as in FIG. 5.

The powder of the solid electrolyte having the APTES self-assembled monolayer provided on the surface thereof was placed into a mold of a predetermined size and cold compacted into a 13 mm wide, 2 mm thick pellet shape by applying a predetermined pressure for a predetermined period of time. In order to achieve stability in the atmosphere, the manufactured pellet-shaped solid electrolyte was left for a predetermined period of time under conditions of room temperature and a relative humidity of about 10 to 20%. Ti electrodes were brought into contact with both sides of the pellet-shaped solid electrolyte to form a cell. The ionic conductivity of the solid electrolyte was measured by using a frequency response analyzer (Solartron HF 1225) to apply alternating impedance in the range of 10⁻¹-10⁵ Hz.

### Experimental Example 2

Other than adding 3-aminopropyltriethoxysilane (APTES) in a concentration of 5 mM to the toluene solution, the same process as in Experimental Example 1 was performed.

### Comparative Example 1

A powder of the solid electrolyte lacking the protective layer (APTES self-assembled monolayer) was cold compacted into the same pellet shape as in Experimental Example 1. Afterwards, the ionic conductivity of the solid electrolyte was measured under the same conditions as in Experimental Example 1.

Referring to FIG. 6, the solid electrolytes manufactured from Experimental Example 1, Experimental Example 2, and Comparative Example 1, respectively, were exposed to moisture, and the ionic conductivities of the solid electrolytes with respect to exposure time was measured. In the case in which no protective layer was provided on the surface of the solid electrolyte (Comparative Example 1), the ionic conductivity of the solid electrolyte decreased rapidly with the exposure time. Conversely, when the protective layer was provided on the surface of the solid electrolyte (Experimental Examples 1 and 2), it was observed that the decrease in the ionic conductivity of the solid electrolyte was smaller. Moreover, in Experimental Examples 1 and 2, it was observed that the decrease in ionic conductivity becomes smaller with increased concentration of organosilanes (for example, APTES) in the mixed solution.

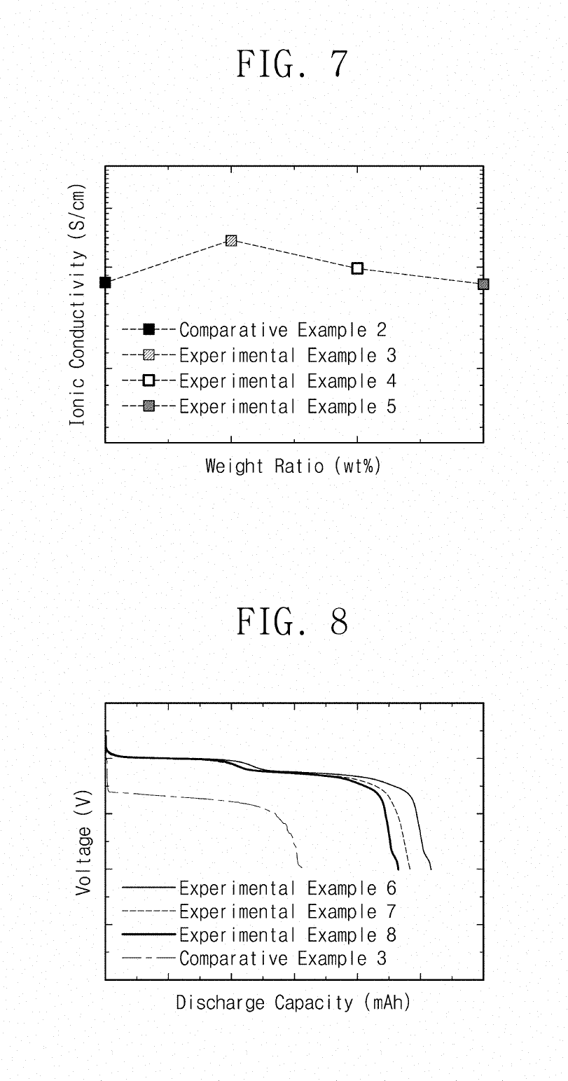

FIG. 7 is a graph analyzing the ionic conductivity of a solid electrolyte film prepared by coating with a solid electrolyte composition.

### Experimental Example 3

A base solution was prepared by dissolving 0.75 g of ethylene-vinylacetate in 9 g of toluene, which is an aprotic solvent. A solid electrolyte composition was prepared by dissolving in the base solution, 14.25 g of the powder of the solid electrolyte having the protective layer (APTES self-assembled monolayer), which was prepared in Experimental Example 1. The solid electrolyte composition was coated onto a Teflon casing holder, and the toluene solvent was dried. A 250 μm thick solid electrolyte film having a 5 cm×5 cm surface was thereby prepared. A 2 cm×2 cm standard SUS/SUS symmetric cell was configured by bringing stainless steel (SUS) electrodes into contact with both sides of the solid electrolyte film. Resistance was measured using an impedance measurement device, and an ionic conductivity value for the solid electrolyte film was derived from the resistance value.

### Experimental Example 4

A base solution was prepared by dissolving 1.5 g of ethylene-vinylacetate in 9 g of toluene, which is an aprotic solvent. A solid electrolyte composition was prepared by dissolving in the base solution, 13.5 g of the powder of the solid electrolyte having the protective layer (APTES self-assembled monolayer), which was prepared in Experimental Example 1. Afterwards, a solid electrolyte film was prepared by the same method as in Experimental Example 3, and the solid electrolyte film was used to configure a SUS/SUS symmetric cell in the same way as in Experimental Example 3. An ionic conductivity value for the solid electrolyte film was derived using the same method as in Experimental Example 3.

### Experimental Example 5

A base solution was prepared by dissolving 1.5 g of ethylene-vinylacetate in 9 g of toluene, which is an aprotic solvent. A solid electrolyte composition was prepared by dissolving in the base solution, 12.75 g of the powder of the solid electrolyte having the protective layer (APTES self-assembled monolayer), which was prepared in Experimental Example 1. Afterwards, a solid electrolyte film was prepared by the same method as in Experimental Example 3, and the solid electrolyte film was used to configure a SUS/SUS symmetric cell in the same way as in Experimental Example 3. An ionic conductivity value for the solid electrolyte film was derived using the same method as in Experimental Example 3.

### Comparative Example 2

A 250 μm thick solid electrolyte pellet having a 5 cm×5 cm surface was manufactured by applying pressure to the sulfide solid electrolyte having the chalcogenide glass-ceramic structured 75Li₂S25P₂S₅ (Li₇P₃S₁₁) composition.

Referring to FIG. 7, it was observed that the solid electrolyte films prepared using wet processing (Experimental Examples 3, 4, and 5) exhibit similar ionic conductivity properties to the solid electrolyte pellet manufactured using dry processing. Moreover, it was observed that the ionic conductivity of the solid electrolyte film decreases as the weight ratio of the polymer binder (for example, ethylene-vinylacetate) with respect to the solid electrolyte provided with the protective layer increases.

FIG. 8 is a graph illustrating the performance of a half-cell manufactured by coating a solid electrolyte composition directly onto an electrode.

### Experimental Example 6

A slurry for electrodes was prepared such that lithium cobalt oxide, a conductive material (Super-P), and a polymer binder (PVDF) had a weight ratio of 90:5:5. A 50 μm thick positive electrode layer (2 cm×2 cm standard) was manufactured by coating the slurry for electrodes onto an aluminum current collector and drying. A 50 μm thick solid electrolyte layer was manufactured by coating the solid electrolyte composition, prepared in Experimental Example 3, directly onto the positive electrode layer and drying. A half-cell was manufactured using a lithium negative electrode as a negative electrode layer. The design capacity of the half-cell was 2 mAh, and cell performance was measured under constant current-constant voltage charging and constant current discharge conditions using a current of 0.2 mAh and a voltage between 3.0 and 4.2 V.

### Experimental Example 7

A 50 μm thick solid electrolyte layer was manufactured by coating the solid electrolyte composition, prepared in Experimental Example 4, directly onto the positive electrode layer manufactured in Experimental Example 6. Afterwards, a half-cell was manufactured and cell performance was measured in the same way as in Experimental Example 6.

### Experimental Example 8

A 50 μm thick solid electrolyte layer was manufactured by coating the solid electrolyte composition, prepared in Experimental Example 5, directly onto the positive electrode layer manufactured in Experimental Example 6. Afterwards, a half-cell was manufactured and cell performance was measured in the same way as in Experimental Example 6.

### Comparative Example 3

A 250 μm thick solid electrolyte pellet having a 5 cm×5 cm surface was manufactured by applying pressure to the sulfide solid electrolyte having the chalcogenide glass-ceramic structured 75Li₂S25P₂S₅ (Li₇P₃S₁₁) composition. A half-cell was manufactured using the solid electrolyte pellet and the same positive electrode layer and negative electrode layer as in Experiment Example 6, and cell performance was measured.

Referring to FIG. 8, it was observed that the half-cells including the solid electrolyte layer formed using wet processing (Experimental Examples 6, 7, and 8) have higher discharge capacities than the half-cell that includes the solid electrolyte pellet formed using dry processing (Comparative Example 3).

According to embodiments of the inventive concept, a protective layer may be provided on a surface of a solid electrolyte. The protective layer may protect the solid electrolyte from external moisture and oxygen. A solid electrolyte composition may be formed by mixing the solid electrolyte, on which the protective layer is provided, an aprotic solvent, and a polymer binder. During wet processing using the solid electrolyte composition, the solid electrolyte may be protected by the protective layer. Accordingly, the wet processing may be performed in a stable manner. Moreover, when a solid electrolyte layer (or a solid electrolyte film) is formed by performing wet processing using the solid electrolyte composition, a large surface of a all-solid-state battery may be conveniently manufactured.

According to embodiments of the inventive concept, the solid electrolyte composition capable of stable wet processing, and a method for preparing the same may be provided.

Moreover, a method may be provided for manufacturing an all-solid-state battery which is easily manufactured, and in which surface area expansion is convenient.

The above descriptions of embodiments of the present invention provide examples for describing the present invention. Thus, the present invention is not limited to the above embodiments, and it is clear that various changes and modifications can be made, for instance, by combining the above embodiments, by one with ordinary skill in the art within the spirit and scope of the present invention.

What is claimed is:

1. A solid electrolyte composition comprising:
a solid electrolyte with a protective layer provided on a surface thereof; and
a polymer binder, wherein the protective layer includes at least one of
an inorganic layer, including at least one of an oxide, a nitride, and a sulfide,
an organic layer, including a polydopamine derivative, and
a self-assembled monolayer, including an organosilane.

2. The solid electrolyte composition of claim 1, wherein the organosilane is an organic material selected from the group consisting of phenethyltrichlorosilane (PETCS), phenyltrichlorosilane (PTCS), benzyltrichlorosilane (BZTCS), tolyltrichlorosilane (TTCS), 2-{(trimethoxysilyl)ethyl}-2-pyridine (PYRTMS), 4-biphenylyltrimethowysilane (BPTMS), octadecyltrichlorosilane (OTS), 1-naphthyltrimehtoxysilane (NAPTMS), 1-{(trimethoxysilyl)methyl}naphthalene (MNATMS), (9-methylanthracenyl)trimethoxysilane (MANTMS}, 3-aminopropyltriethoxysilane (APTES), and derivatives thereof.

3. The solid electrolyte composition of claim 1, wherein:
the oxide includes at least one of C, Al, Si Ti, Fe, Co, Ni, Cu, Zn, Ga, Ge, Mo, Ru, Rh, Pd, Ag, Ta, W, Pt, Li, Be, B, Mg, Al, Si, P, Ca, Sc, Ti, V, Cr, Mn, Fe, Co, Ni, Cu, Zn, Ga, Ge, Sr, Y, Zr, Nb, Ru, Rh, Pd, In, Sn, Sb, Ba, La, Ce, Pr, Nd, Sm, Eu, Gd, Tb, Yb, Lu, Hf, W, Ir, Pt, and Pb;
the nitride includes at least one of B, Al, Si, Ti, Cu, Ga, Zr, Nb, Mo, In, Hf, Ta, and W; and
the sulfide includes at least one of Ca, Ti, Mn, Cu, Zn, Sr, Y, Cd, In, Sn, Sb, Ba, La, and W.

4. The solid electrolyte composition of claim 1, wherein the solid electrolyte is a chalcogenide solid electrolyte.

5. The solid electrolyte composition of claim 1, wherein the solid electrolyte is a chalcogenide solid electrolyte that includes a sulfide.

6. The solid electrolyte composition of claim 5, wherein the solid electrolyte includes at least one of Li₁₀SnP₂S₁₂, Li₄₋ₓSn₁₋ₓAsₓS₄ (x=0-100), Li_{3.25}Ge_{0.25}P_{0.75}S₄, Li₁₀GeP₂S₁₂, Li₆PS₅Cl, Li₂SP₂S₅, (x)Li₂S(100−x)P₂S₅ (x=0-100), Li₂P₂S₅, Li₂SSiS₂Li₃N, Li₂SP₂S₅LiI, (100−x)(0.6Li₂S.0.4SiS₂).xLixMOy (M=Si, P, Ge, B, Al, Ga, or In, x=0-100, y is a value determined by x in order to achieve electroneutrality), Li₂SGeS₂, and Li₂SB₂S₃LiI.

7. The solid electrolyte composition of claim 1, wherein a thickness of the protective layer ranges from 0.1 nm to 500 nm.

8. The solid electrolyte composition of claim 1, further comprising an aprotic solvent, wherein the aprotic solvent includes at least one of tetrahydrofuran (THF), acetone, dimethylformamide (DMF), dimethylsulfoxide (DMSO), n-methylpyrrolidone (NMP), benzene, chlorobenzene, n-hexane, toluene, xylene, n-octane, acetonitrile (AN), diethylether, dichloromethane, ethylacetate, cyclohexane, pentane, chloroform, and methylethylketone (MEK).

9. The solid electrolyte composition of claim 1, wherein the polymer binder includes at least one of polyethylene, polypropylene, ethylene-vinylacetate copolymer, ethylene-vinylalcohol copolymer, ethylene-vinylacetylic acid copolymer, butadiene rubber, styrene butadiene rubber, and nitrile butadiene rubber.

10. The solid electrolyte composition of claim 1, wherein a weight ratio of the solid electrolyte provided with the protective layer, and the polymer binder ranges from 99.9:0.1 to 50:50.

11. A method for preparing a solid electrolyte composition, the method comprising:
providing a solid electrolyte;
forming a protective layer on a surface of the solid electrolyte;
providing a base solution, in which a polymer binder is dissolved in an aprotic solvent; and
adding to the base solution, the solid electrolyte provided with the protective layer, wherein the protective layer includes at least one of
an inorganic layer, including at least one of an oxide, a nitride, and a sulfide,
an organic layer, including a polydopamine derivative, and
a self-assembled monolayer, including an organosilane.

12. The method of claim 11, wherein the forming the protective layer includes using an atomic layer deposition process to form the inorganic layer on the surface of the solid electrolyte.

13. The method of claim 11, wherein the forming the protective layer includes forming the organic layer on the surface of the solid electrolyte by using a dip-coating process,
wherein the forming the organic layer includes performing the dip-coating process using a solution in which the polydopamine derivative is dissolved.

14. The method of claim 11, wherein the forming the protective layer includes forming the self-assembled monolayer on the surface of the solid electrolyte by using a dip-coating process,
wherein the forming the self-assembled monolayer includes performing the dip-coating process using a solution in which the organosilane is dissolved.

15. The method of claim 14, wherein a concentration of the organosilane in the solution ranges from 1 mM to 1 M.

16. The method of claim 14, wherein the solution is formed using a solvent selected from among toluene, hexane, chloroform, diethylether, cyclohexane, benzene, and combinations thereof.

17. The method of claim 14, wherein a reaction time for the dip-coating process ranges from 0.1 hours to 24 hours.

18. The method of claim 11, wherein a concentration of the polymer binder in the base solution ranges from 1 wt % to 50 wt %.

19. The method of claim 11, wherein the solid electrolyte provided with the protective layer is provided in a weight ratio of 99.9:0.1 to 50:50 with respect to the polymer binder.

20. A method for manufacturing an all-solid-state battery, the method comprising:
providing a positive electrode layer and a negative electrode layer; and
forming a solid electrolyte layer by performing wet processing using a solid electrolyte composition, wherein the solid electrolyte layer is provided between the positive electrode layer and the negative electrode layer, and the solid electrolyte composition includes
a solid electrolyte with a protective layer provided on a surface thereof,
an aprotic solvent, and
a polymer binder, the protective layer including at least one of an inorganic layer, including at least one of an oxide, a nitride, and a sulfide, an organic layer, including a polydopamine derivative, and a self-assembled monolayer, including an organosilane.
